(19) United States
(12) Patent Application Publication
(10) Pub. No.: US 2024/0418339 A1
(43) Pub. Date: Dec. 19, 2024

(54) ELECTRONIC DEVICE

(71) Applicant: CARUX TECHNOLOGY PTE. LTD., SINGAPORE (SG)

(72) Inventors: Ming-Yao CHANG, Tainan (Tainan Science Park) (TW); Ching-Lun TSENG, Tainan (Tainan Science Park) (TW); Wei-Hsuan LEE, Tainan (Tainan Science Park) (TW)

(21) Appl. No.: 18/659,611

(22) Filed: May 9, 2024

(30) Foreign Application Priority Data
Jun. 16, 2023 (CN) 202310714661.X

(51) Int. Cl. F21S 43/20; F21S 43/14; F21V 23/04; F21Y 115/10; H05B 45/12; H05B 45/14; H05B 47/11

(52) U.S. Cl. CPC F21S 43/255; F21S 43/14; F21V 23/0464; H05B 45/12; H05B 45/14; H05B 47/11; F21Y 2115/10

(57) ABSTRACT

An electronic device is provided. The electronic device includes an electronic unit, a vehicle control unit and a sensing unit. The electronic unit includes a light-emitting unit that provides a first emitted light and a first light-filtering unit disposed on the light-emitting unit. The first light-filtering unit includes a substrate and a first light-conversion layer disposed on the substrate. The vehicle control unit is electrically connected to the light-emitting unit. The sensing unit is electrically connected to the vehicle control unit. The vehicle control unit modulates the intensity of the first emitted light based on the sensing signal from the sensing unit. The modulated first emitted light passes through the first light-filtering unit to form a second emitted light.

### CROSS REFERENCE TO RELATED APPLICATIONS

This application claims priority of China Patent Application No. 202310714661.X, filed on Jun. 16, 2023, the entirety of which is incorporated by reference herein.

### BACKGROUND OF THE INVENTION

### Field of the Invention

The present invention relates to an electronic device, and, in particular, to an electronic device with an adjustable light-filtering unit.

### Description of the Related Art

In order to meet user demands regarding the color of the pilot lamp in a car, the automobile industry is currently adjusting the color of these pilot lamps by replacing LEDs. However, this method will cause problems with chromaticity deviation.

### BRIEF SUMMARY OF THE INVENTION

In accordance with one embodiment of the present disclosure, an electronic device is provided. The electronic device includes an electronic unit, a vehicle control unit and a sensing unit. The electronic unit includes a light-emitting unit and a first light-filtering unit. The light-emitting unit provides a first emitted light. The first light-filtering unit is disposed on the light-emitting unit. The first light-filtering unit includes a substrate and a first light-conversion layer disposed on the substrate. The vehicle control unit is electrically connected to the light-emitting unit. The sensing unit is electrically connected to the vehicle control unit and transmits a sensing signal to the vehicle control unit. The vehicle control unit modulates the intensity of the first emitted light based on the sensing signal from the sensing unit. A modulated first emitted light passes through the first light-filtering unit to form a second emitted light.

In accordance with one embodiment of the present disclosure, an electronic device is provided. The electronic device includes an electronic unit, a vehicle control unit, a first control unit and a second control unit. The electronic unit includes a first light-emitting unit, a second light-emitting unit, a first light-filtering unit and a second light-filtering unit. The first light-emitting unit provides a first emitted light. The second light-emitting unit provides another first emitted light. The first light-filtering unit is disposed on the first light-emitting unit and the second light-emitting unit. The first light-filtering unit includes a substrate, a first light-conversion layer and a second light-conversion layer. The first light-conversion layer is disposed on the substrate and corresponds to the first light-emitting unit. The second light-conversion layer is disposed on the substrate and corresponds to the second light-emitting unit. The second light-filtering unit is disposed on the first light-emitting unit and the second light-emitting unit. The first control unit is electrically connected to the vehicle control unit. The second control unit is electrically connected to the first light-emitting unit, the second light-emitting unit and the vehicle control unit. Based on a control signal from the first control unit, the vehicle control unit controls the light emission of the first light-emitting unit and the second light-emitting unit through the second control unit, so as to modulate the light intensity of the first emitted light and the other first emitted light. The first emitted light passes through the first light-filtering unit to form a second emitted light. The other first emitted light passes through the first light-filtering unit to form another second emitted light. The second emitted light and the other second emitted light pass through the second light-filtering unit to form a third emitted light.

In accordance with one embodiment of the present disclosure, an electronic device is provided. The electronic device includes an electronic unit, a vehicle control unit, a control unit and a driving unit. The electronic unit includes a light-emitting unit and a light-filtering unit. The light-emitting unit provides a first emitted light. The light-filtering unit is disposed on the light-emitting unit. The light-filtering unit includes a substrate and a light-conversion layer disposed on the substrate. The vehicle control unit is electrically connected to the light-emitting unit. The control unit is electrically connected to the vehicle control unit. The driving unit is electrically connected to the vehicle control unit. Based on the control signal from the control unit, the vehicle control unit controls the rotation of the light-filtering unit through the driving unit. The first emitted light passes through the light-filtering unit to form a second emitted light.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows internal electrical connections of an electronic device in accordance with one embodiment of the present disclosure;

FIG. 2A shows a cross-sectional view of an electronic unit in an electronic device in accordance with one embodiment of the present disclosure;

FIG. 2B shows a top view of an electronic unit in an electronic device in accordance with one embodiment of the present disclosure;

FIG. 3 shows a cross-sectional view of an electronic unit in an electronic device in accordance with one embodiment of the present disclosure;

FIG. 4 shows a cross-sectional view of an electronic unit in an electronic device in accordance with one embodiment of the present disclosure;

FIG. 5 shows a cross-sectional view of an electronic unit in an electronic device in accordance with one embodiment of the present disclosure;

FIG. 6 shows a cross-sectional view of an electronic unit in an electronic device in accordance with one embodiment of the present disclosure;

FIG. 7 shows internal electrical connections of an electronic device in accordance with one embodiment of the present disclosure;

FIG. 8 shows a cross-sectional view of an electronic unit in an electronic device in accordance with one embodiment of the present disclosure;

FIG. 9 shows a cross-sectional view of an electronic unit in an electronic device in accordance with one embodiment of the present disclosure;

FIG. 10 shows internal electrical connections of an electronic device in accordance with one embodiment of the present disclosure;

FIG. 11 shows a cross-sectional view of an electronic unit in an electronic device in accordance with one embodiment of the present disclosure;

FIG. 12 shows a schematic diagram of operation of some components in an electronic device in accordance with one embodiment of the present disclosure; and

FIG. 13 shows a schematic diagram of operation of some components in an electronic device in accordance with one embodiment of the present disclosure.

### DETAILED DESCRIPTION OF THE INVENTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the present disclosure is an approximate value. Namely, the meaning of “about”, “around” and “substantially” may be implied if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

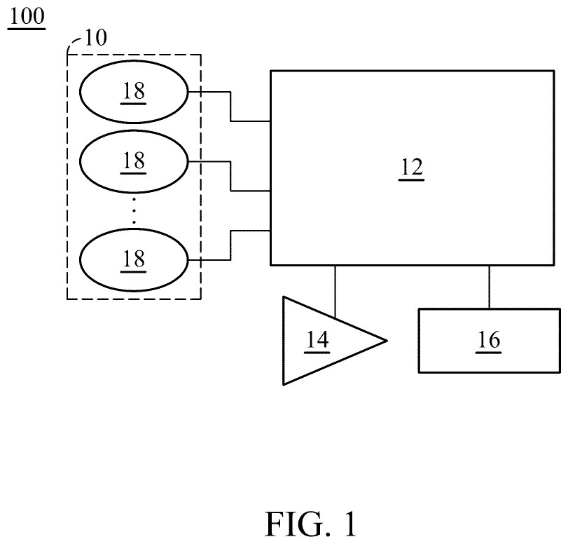

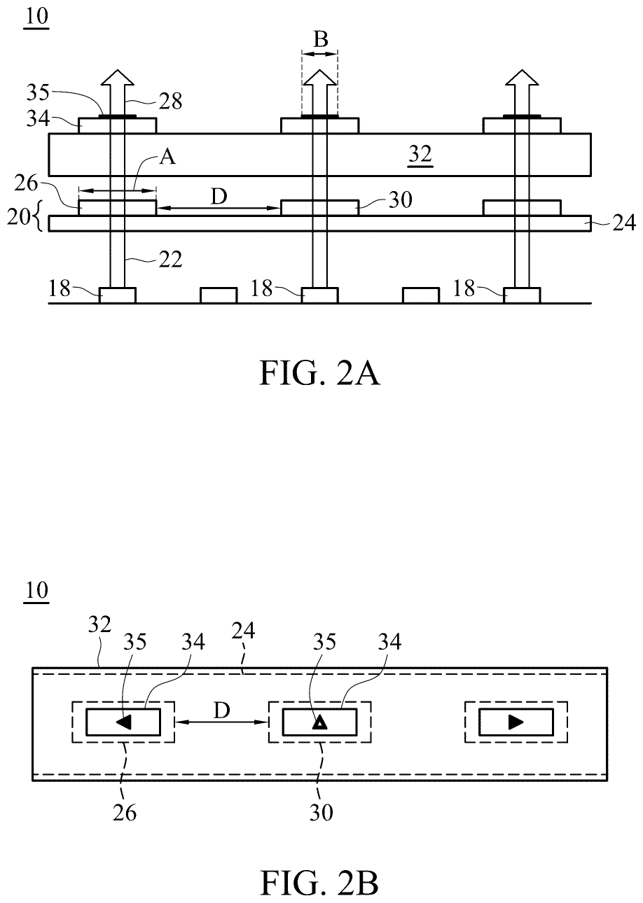

Referring to FIGS. 1, 2A and 2B, in accordance with one embodiment of the present disclosure, an electronic device 100 is provided. FIG. 1 shows internal electrical connections of the electronic device 100. FIG. 2A shows a cross-sectional view of an electronic unit 10 in the electronic device 100. In one embodiment, the electronic device 100 may be, for example, a vehicle center console, a vehicle dashboard, a vehicle operating device, a vehicle display device, etc.

The electronic device 100 includes an electronic unit 10, a vehicle control unit 12, a sensing unit 14 and a power supply 16. As shown in FIG. 2A, the electronic unit 10 includes a light-emitting unit 18 and a first light-filtering unit 20. The light-emitting unit 18 provides a first emitted light 22. The first light-filtering unit 20 is disposed on the light-emitting unit 18. The first light-filtering unit 20 includes a substrate 24 and a first light-conversion layer 26 disposed on the substrate 24. As shown in FIG. 1, the vehicle control unit 12 is electrically connected to the light-emitting unit 18 in the electronic unit 10. The sensing unit 14 is electrically connected to the vehicle control unit 12 and transmits a sensing signal to the vehicle control unit 12. The power supply 16 is electrically connected to the vehicle control unit 12. Specifically, the vehicle control unit 12 modulates the intensity of the first emitted light 22 based on the sensing signal from the sensing unit 14. The modulated first emitted light 22 passes through the first light-filtering unit 20 to form a second emitted light 28, as shown in FIG. 2A.

In one embodiment, the electronic unit 10 may include, for example, indicator lamps, warning lamps, atmosphere lamps, etc., but any electronic component with a light-emitting function in a vehicle may be implemented, but it is not limited thereto. For example, when the detected ambient light is stronger, the light intensity of the first emitted light 22 is stronger; otherwise, the weaker the ambient light is, the lower the light intensity of the first emitted light 22 is.

In accordance with some embodiments, the light-emitting unit 18 may include submillimeter light-emitting diodes (mini LEDs), micro light-emitting diodes (micro LEDs), or quantum-dot light-emitting diodes (quantum-dot LEDs, QLEDs/QDLEDs), but the present disclosure is not limited thereto, and other suitable light-emitting components are also applicable to the present disclosure.

In accordance with some embodiments, the vehicle control unit 12 can obtain relevant information and data required by the vehicle, process the data, and then issue instructions to the corresponding drivers (actuators). The vehicle control unit 12 may include a central control system or a local controller, such as an integrated circuit (IC), an electronic control unit (ECU), a microcontroller (MCU), or a computer, but it is not limited thereto.

In accordance with some embodiments, the sensing unit 14 may include an ambient-light sensor (ALS), for detecting the brightness of the ambient light and feeding it back to the vehicle control unit 12. In accordance with some embodiments, the sensing unit 14 may include camera or charge coupled device (CCD), but the present disclosure is not limited thereto, and other suitable light-sensing components are also applicable to the present disclosure. The sensing signals may include, for example, visible light, ultraviolet light (UV light), infrared light or light intensity signals of radiation light types in various bands, and may also be environmental signals, moving object detection signals, biological sensing signals or combinations of the above signals. For example, the sensing unit 14 can be used to sense physiological information such as the driver's sight position or physiological condition.

In accordance with some embodiments, the substrate 24 may include a transparent substrate. In accordance with some embodiments, the substrate 24 may include polyethylene terephthalate (PET) or polyimide (PI), but the present disclosure is not limited thereto, and other suitable transparent substrate materials are also applicable to the present disclosure.

In accordance with some embodiments, the first light-conversion layer 26 may include organic dyes, inorganic dyes, phosphor materials, fluorescent materials, or quantum-dot particles, but the present disclosure is not limited thereto, and other suitable light-conversion materials that can convert light colors are also suitable for use in the present disclosure.

Referring to FIG. 2A, the first light-filtering unit 20 further includes a second light-conversion layer 30 disposed on the substrate 24. The first light-conversion layer 26 is separated from the second light-conversion layer 30 by a distance D. In one embodiment, the first light-conversion layer 26 is different in color from the second light-conversion layer 30. The difference in color can be, for example, that the same incident light is respectively irradiated and penetrated through the first light-conversion layer 26 and the second light-conversion layer 30 to form two emitted lights respectively. The transmittance chromaticity coordinates of the two emitted lights are (xa, ya) and (xb, yb) respectively, and meet the following relationship: 0.003<|xa-xb |<0.2 and 0.003<|ya-yb |<0.2. In accordance with some embodiments, the second light-conversion layer 30 may include organic dyes, inorganic dyes, phosphor materials, fluorescent materials, or quantum-dot particles, but the present disclosure is not limited thereto, and other suitable light-conversion materials that can convert light colors are also suitable for use in the present disclosure.

In accordance with some embodiments, the distance D between the first light-conversion layer 26 and the second light-conversion layer 30 may be, for example, one of the following ranges or a combination thereof. The distance D may be 2.0 mm-5.0 mm. The distance D may be 5.0 mm-10.0 mm. The distance D may be 10.0 mm-20.0 mm. The present disclosure is not limited thereto, and other suitable distances between light-conversion layers may also be applicable to the present disclosure.

In accordance with some embodiments, the light transmittance of the first light-filtering unit 20 is less than or equal to 30% and greater than or equal to 45%, less than or equal to 45% and greater than or equal to 60%, less than or equal to 60% and greater than or equal to 80%, but the present disclosure is not limited thereto, and other suitable light transmittance is also applicable to the present disclosure. The light transmittance can be obtained, for example, by first measuring a light to obtain the first light intensity, then passing the light through the first light-filtering unit 20 and measuring the second light intensity of the passing light, and dividing the second light intensity by the first light intensity to obtain light transmittance. The measurement of the light transmittance can be implemented, for example, by a display measurement system (DMS), an image luminance meter (LMK) or other instruments capable of measuring light intensity, or a combination thereof.

Referring to FIG. 2A, the electronic unit 10 further includes a cover plate 32 disposed on the first light-filtering unit 20. The electronic unit 10 further includes a second light-filtering unit 34 disposed on the cover plate 32. The second light-filtering unit 34 may include, for example, a substrate and a light-conversion layer, which are described in the first light-filtering unit 20, and will not be repeated here. In accordance with some embodiments, the second light-filtering unit 34 may include a pattern area 35. In accordance with some embodiments, the surface area A of the first light-conversion layer 26 may be greater than or equal to the surface area B of the pattern area 35 of the second light-filtering unit 34.

Referring to FIG. 2B, a top view of the electronic unit 10, the first light-conversion layer 26 and the second light-conversion layer 30 are disposed on the substrate 24. The first light-conversion layer 26 is separated from the second light-conversion layer 30 by the distance D. The second light-filtering unit 34 is disposed on the cover plate 32. The second light-filtering unit 34 includes the pattern area 35.

In accordance with some embodiments, the first transmittance chromaticity coordinates of the first emitted light 22 are (x1, y1). The second transmittance chromaticity coordinates of the second emitted light 28 are (x2, y2). The first transmittance chromaticity coordinates (x1, y1) of the first emitted light 22 and the second transmittance chromaticity coordinates (x2, y2) of the second emitted light 28 conform to the following relationship: 0.003<|x1-x2|<0.2 and 0.003<|y1-y2|<0.2.

In the embodiment of FIGS. 1 and 2A, in the electronic unit 10, the chromaticity of the emitted light is altered through the first light-filtering unit 20. The sensing signal detected by the sensing unit 14, such as the brightness of the ambient light, is fed back to the vehicle control unit 12. According to the brightness information of the ambient light, the vehicle control unit 12 adjusts the brightness of the light-emitting unit 18, so that the indicator lamp presents an appropriate brightness. For example, in one embodiment, when the brightness of the ambient light is increased, the vehicle control unit 12 increases the brightness of the light-emitting unit 18, and when the brightness of the ambient light is decreased, the vehicle control unit 12 decreases the brightness of the light-emitting unit 18.

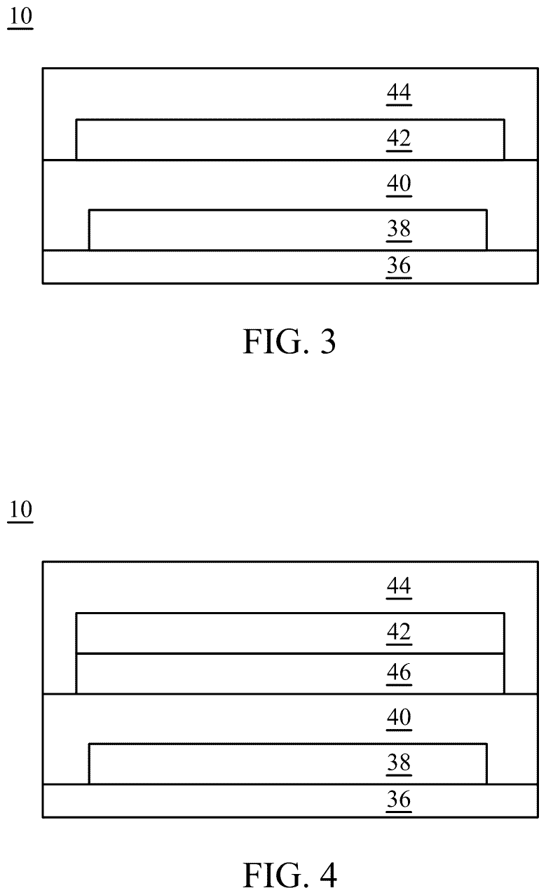

Referring to FIG. 3, in accordance with one embodiment of the present disclosure, the structure of the electronic unit 10 in the electronic device 100 is further illustrated. FIG. 3 shows a cross-sectional view of the electronic unit 10 in the electronic device 100.

As shown in FIG. 3, the electronic unit 10 includes a carrier 36, a light-emitting unit 38, a fixing base 40, a light-filtering unit 42, and a cover plate 44. The light-emitting unit 38 is disposed on the carrier 36. The fixing base 40 is disposed on the light-emitting unit 38. The light-filtering unit 42 is disposed on the fixing base 40. The cover plate 44 is disposed on the light-filtering unit 42. The structure and material of the light-emitting unit 38, the light-filtering unit 42 and the cover plate 44 shown in FIG. 3 are similar to those of the light-emitting unit 18, the first light-filtering unit 20 and the cover plate 32 shown in FIG. 2, which will not be repeated here.

The structure of the electronic unit 10 shown in FIG. 3 can be applied, for example, to a temporary parking indicator button in a car.

Referring to FIG. 4, in accordance with one embodiment of the present disclosure, the structure of the electronic unit 10 in the electronic device 100 is further illustrated. FIG. 4 shows a cross-sectional view of the electronic unit 10 in the electronic device 100.

As shown in FIG. 4, the electronic unit 10 includes a carrier 36, a light-emitting unit 38, a fixing base 40, a diffusion plate 46, a light-filtering unit 42, and a cover plate 44. The light-emitting unit 38 is disposed on the carrier 36. The fixing base 40 is disposed on the light-emitting unit 38. The diffusion plate 46 is disposed on the fixing base 40. The light-filtering unit 42 is disposed on the diffusion plate 46. The cover plate 44 is disposed on the light-filtering unit 42. It should be noted that the difference between the embodiment shown in FIG. 4 and the embodiment shown in FIG. 3 is that, in the embodiment shown in FIG. 4, the diffusion plate 46 is disposed between the light-emitting unit 38 and the light-filtering unit 42. In addition, the structure and material of the light-emitting unit 38, the light-filtering unit 42 and the cover plate 44 shown in FIG. 4 are similar to those of the light-emitting unit 18, the first light-filtering unit 20 and the cover plate 32 shown in FIG. 2, which will not be repeated here.

The structure of the electronic unit 10 shown in FIG. 4 can be applied, for example, to a high beam indicator button in a car.

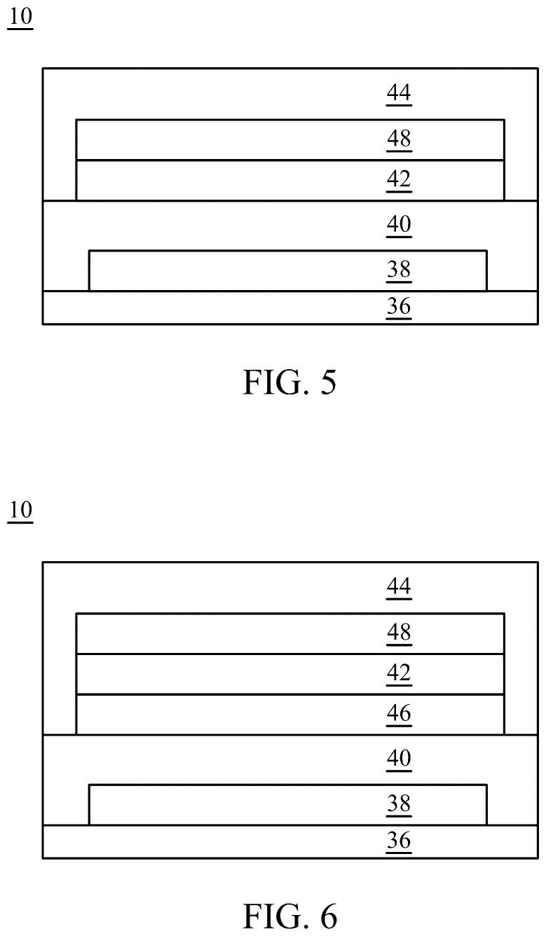

Referring to FIG. 5, in accordance with one embodiment of the present disclosure, the structure of the electronic unit 10 in the electronic device 100 is further illustrated. FIG. 5 shows a cross-sectional view of the electronic unit 10 in the electronic device 100.

As shown in FIG. 5, the electronic unit 10 includes a carrier 36, a light-emitting unit 38, a fixing base 40, a light-filtering unit 42, a touch unit 48, and a cover plate 44. The light-emitting unit 38 is disposed on the carrier 36. The fixing base 40 is disposed on the light-emitting unit 38. The light-filtering unit 42 is disposed on the fixing base 40. The touch unit 48 is disposed on the light-filtering unit 42. The cover plate 44 is disposed on the touch unit 48. It should be noted that the difference between the embodiment shown in FIG. 5 and the embodiment shown in FIG. 3 is that, in the embodiment shown in FIG. 5, the touch unit 48 is disposed on the light-filtering unit 42 and is electrically connected to the vehicle control unit 12 shown in FIG. 1.

In accordance with some embodiments, the touch unit 48 may include sensor glass, but the present disclosure is not limited thereto, and other suitable touch components are also applicable to the present disclosure. In addition, the structure and material of the light-emitting unit 38, the light-filtering unit 42 and the cover plate 44 shown in FIG. 5 are similar to those of the light-emitting unit 18, the first light-filtering unit 20 and the cover plate 32 shown in FIG. 2, which will not be repeated here.

The structure of the electronic unit 10 shown in FIG. 5 can be applied, for example, to an air-conditioning system indicator button in a car.

Referring to FIG. 6, in accordance with one embodiment of the present disclosure, the structure of the electronic unit 10 in the electronic device 100 is further illustrated. FIG. 6 shows a cross-sectional view of the electronic unit 10 in the electronic device 100.

As shown in FIG. 6, the electronic unit 10 includes a carrier 36, a light-emitting unit 38, a fixing base 40, a diffusion plate 46, a light-filtering unit 42, a touch unit 48, and a cover plate 44. The light-emitting unit 38 is disposed on the carrier 36. The fixing base 40 is disposed on the light-emitting unit 38. The diffusion plate 46 is disposed on the fixing base 40. The light-filtering unit 42 is disposed on the diffusion plate 46. The touch unit 48 is disposed on the light-filtering unit 42. The cover plate 44 is disposed on the touch unit 48. It should be noted that the difference between the embodiment shown in FIG. 6 and the embodiment shown in FIG. 3 is that, in the embodiment shown in FIG. 6, the diffusion plate 46 is disposed between the light-emitting unit 38 and the light-filtering unit 42, and the touch unit 48 is disposed on the light-filtering unit 42 and is electrically connected to the vehicle control unit 12 shown in FIG. 1. In accordance with some embodiments, the touch unit 48 may include sensor glass, but the present disclosure is not limited thereto, and other suitable touch components are also applicable to the present disclosure. In addition, the structure and material of the light-emitting unit 38, the light-filtering unit 42 and the cover plate 44 shown in FIG. 6 are similar to those of the light-emitting unit 18, the first light-filtering unit 20 and the cover plate 32 shown in FIG. 2, which will not be repeated here.

The structure of the electronic unit 10 shown in FIG. 6 can be applied, for example, to a volume indicator button in a car.

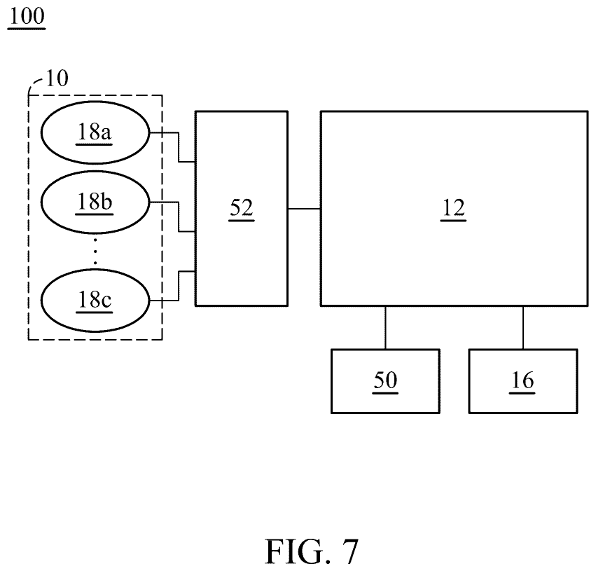

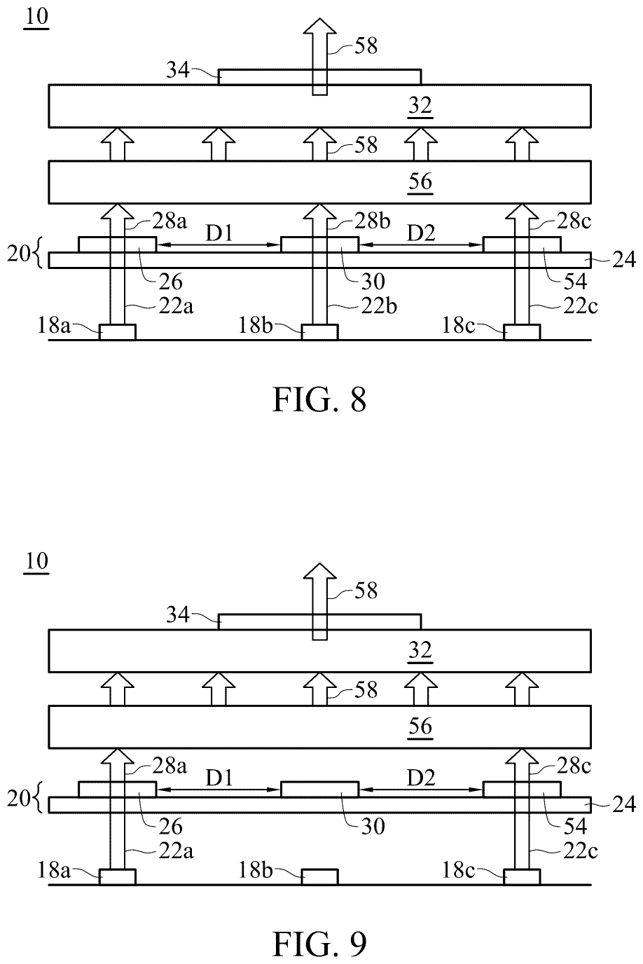

Referring to FIGS. 7 and 8, in accordance with one embodiment of the present disclosure, an electronic device 100 is provided. FIG. 7 shows internal electrical connections of the electronic device 100. FIG. 8 shows a cross-sectional view of an electronic unit 10 in the electronic device 100.

The electronic device 100 includes an electronic unit 10, a vehicle control unit 12, a first control unit 50, a second control unit 52 and a power supply 16. As shown in FIG. 8, the electronic unit 10 includes a first light-emitting unit 18a, a second light-emitting unit 18b, a third light-emitting unit 18c and a first light-filtering unit 20. The first light-emitting unit 18a provides a first emitted light 22a. The second light-emitting unit 18b provides a first emitted light 22b. The third light-emitting unit 18c provides a first emitted light 22c. The first light-filtering unit 20 is disposed on the first light-emitting unit 18a, the second light-emitting unit 18b and the third light-emitting unit 18c. The first light-filtering unit 20 includes a substrate 24, a first light-conversion layer 26, a second light-conversion layer 30 and a third light-conversion layer 54. The first light-conversion layer 26 is disposed on the substrate 24 and corresponds to the first light-emitting unit 18a. The second light-conversion layer 30 is disposed on the substrate 24 and corresponds to the second light-emitting unit 18b. The third light-conversion layer 54 is disposed on the substrate 24 and corresponds to the third light-emitting unit 18c.

As shown in FIG. 7, the first control unit 50 is electrically connected to the vehicle control unit 12. The second control unit 52 is electrically connected to the light-emitting units (for example, the first light-emitting unit 18a, the second light-emitting unit 18b and the third light-emitting unit 18c) in the electronic unit 10 and the vehicle control unit 12. The power supply 16 is electrically connected to the vehicle control unit 12. It should be noted that, based on the control signal from the first control unit 50, the vehicle control unit 12 controls the light emission of the first light-emitting unit 18a, the second light-emitting unit 18b and the third light-emitting unit 18c through the second control unit 52, so as to modulate the light intensity of the first emitted light (22a, 22b and 22c). The first emitted light 22a passes through the first light-filtering unit 20 to form a second emitted light 28a. The first emitted light 22b passes through the first light-filtering unit 20 to form a second emitted light 28b. The first emitted light 22c passes through the first light-filtering unit 20 to form a second emitted light 28c, as shown in FIG. 8.

In accordance with some embodiments, the first light-emitting unit 18a, the second light-emitting unit 18b and the third light-emitting unit 18c may include submillimeter light-emitting diodes (mini LEDs), micro light-emitting diodes (micro LEDs), or quantum-dot light-emitting diodes (quantum-dot LEDs, QLEDs/QDLEDs), but the present disclosure is not limited thereto, and other suitable light-emitting components are also applicable to the present disclosure.

In accordance with some embodiments, the vehicle control unit 12 may include a central control system or a local controller, such as an integrated circuit (IC), a microcontroller (MCU), or a computer.

In accordance with some embodiments, the first control unit 50 may include controller area network (CAN), gigabit multimedia serial links 3 (GMSL 3), electronic control unit (ECU), but the present disclosure is not limited thereto, and other suitable control components are also applicable to the present disclosure. In accordance with some embodiments, the second control unit 52 may include local-dimming control unit, but the present disclosure is not limited thereto, and other suitable control components are also applicable to the present disclosure.

In accordance with some embodiments, the substrate 24 may include a transparent substrate. In accordance with some embodiments, the substrate 24 may include polyethylene terephthalate (PET) or polyimide (PI), but the present disclosure is not limited thereto, and other suitable transparent substrate materials are also applicable to the present disclosure.

In accordance with some embodiments, the first light-conversion layer 26, the second light-conversion layer 30 and the third light-conversion layer 54 may include organic dyes, inorganic dyes, phosphor materials, fluorescent materials, or quantum-dot particles, but the present disclosure is not limited thereto, and other suitable light-conversion materials that can convert light colors are also suitable for use in the present disclosure.

Referring to FIG. 8, the first light-conversion layer 26 is separated from the second light-conversion layer 30 by a first distance D1. The second light-conversion layer 30 is separated from the third light-conversion layer 54 by a second distance D2. In accordance with some embodiments, the first distance D1 between the first light-conversion layer 26 and the second light-conversion layer 30 and the second distance D2 between the second light-conversion layer 30 and the third light-conversion layer 54 may be, for example, one of the following ranges or a combination thereof. The second distance D2 may be 2.0 mm-5.0 mm. The second distance D2 may be 5.0 mm-10.0 mm. The second distance D2 may be 10.0 mm-20.0 mm. The present disclosure is not limited thereto, and other suitable distances between light-conversion layers may also be applicable to the present disclosure. In accordance with some embodiments, the light transmittance of the first light-filtering unit 20 is between about 30% and about 80%, but the present disclosure is not limited thereto, and other suitable light transmittance is also applicable to the present disclosure.

Referring to FIG. 8, the electronic unit 10 further includes a light-guide layer 56 disposed on the first light-filtering unit 20, and the second emitted light passes through the light-guide layer to form the third emitted light. In accordance with some embodiments, the light-guide layer 56 may include a light-guide column or a light-guide plate, but the present disclosure is not limited thereto, and other suitable light-guide components are also applicable to the present disclosure. The second emitted light (28a, 28b and 28c) is mixed by the light-guide layer 56 to form a third emitted light 58.

As shown in FIG. 8, the electronic unit 10 further includes a cover plate 32 disposed on the light-guide layer 56. The electronic unit 10 further includes a second light-filtering unit 34 disposed on the cover plate 32. In accordance with some embodiments, the second light-filtering unit 34 may include a pattern area (not shown).

In the embodiment of FIGS. 7 and 8, a control signal (obtained by, for example, voice or touch) is input to the vehicle control unit 12 through the first control unit 50. The first light-emitting unit 18a, the second light-emitting unit 18b, and the third light-emitting unit 18c are instructed to emit light simultaneously by the second control unit 52 (for example, a local-dimming control unit). By controlling the first light-emitting unit 18a, the second light-emitting unit 18b, and the third light-emitting unit 18c to emit light at the same time and cooperating with the light-guide layer 56 to generate a light-mixing effect, the final color of the indicator lamp pattern is altered. For example, the first emitted light 22a passes through the first light-filtering unit 20 to form a blue second emitted light 28a, the first emitted light 22b passes through the first light-filtering unit 20 to form a red second emitted light 28b, and the first emitted light 22c passes through the first light-filtering unit 20 to form a white second emitted light 28c. The second emitted light (28a, 28b and 28c) is mixed by the light-guide layer 56 to form a purple third emitted light 58, and then passes through the second light-filtering unit 34.

Referring to FIGS. 7 and 9, different lighting modes from the embodiment shown in FIGS. 7 and 8 are illustrated.

In the embodiment of FIGS. 7 and 9, a control signal (obtained by, for example, voice or touch) is input to the vehicle control unit 12 through the first control unit 50. The second control unit 52 (for example, a local-dimming control unit) instructs the first light-emitting unit 18a and the third light-emitting unit 18c to emit light simultaneously, but the second light-emitting unit 18b does not emit light. By controlling the first light-emitting unit 18a, the second light-emitting unit 18b, and the third light-emitting unit 18c to emit light locally and cooperating with the light-guide layer 56 to form a light-mixing effect, the final color of the indicator lamp pattern is altered. For example, the first emitted light 22a passes through the first light-filtering unit 20 to form a blue second emitted light 28a, and the first emitted light 22c passes through the first light-filtering unit 20 to form a white second emitted light 28c. The second emitted light (28a and 28c) is mixed by the light-guide layer 56 to form a light-blue third emitted light 58.

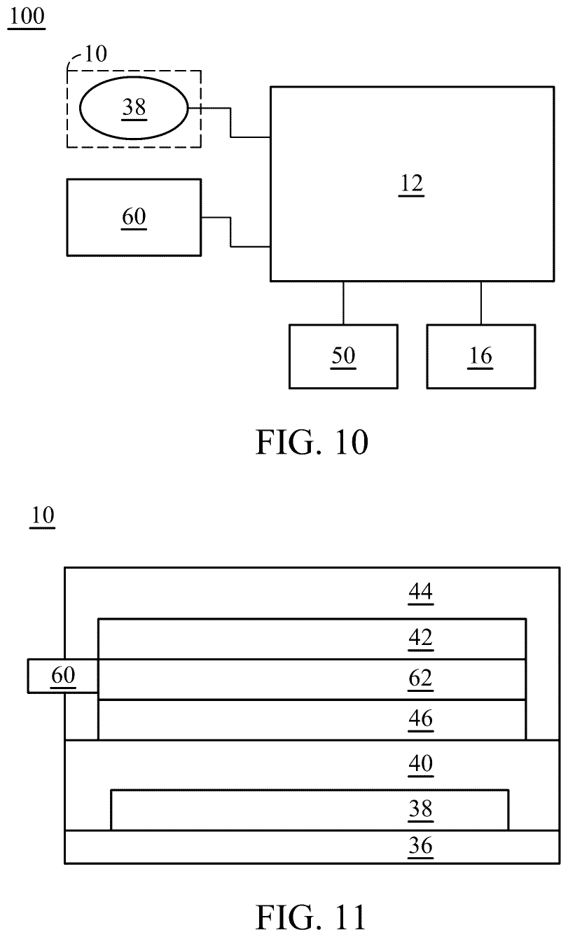

Referring to FIGS. 10 and 11, in accordance with one embodiment of the present disclosure, an electronic device 100 is provided. FIG. 10 shows internal electrical connections of the electronic device 100. FIG. 11 shows a cross-sectional view of an electronic unit 10 in the electronic device 100.

As shown in FIG. 10, the electronic device 100 includes an electronic unit 10, a vehicle control unit 12, a control unit 50, a driving unit 60 and a power supply 16. The vehicle control unit 12 is electrically connected to a light-emitting unit 38 in the electronic unit 10. The control unit 50 is electrically connected to the vehicle control unit 12. The driving unit 60 is electrically connected to the vehicle control unit 12. The power supply 16 is electrically connected to the vehicle control unit 12. It should be noted that, based on the control signal from the control unit 50, the vehicle control unit 12 instructs the driving unit 60 to control rotation of a light-filtering unit 42 in the electronic unit 10. The driving unit 60 may include, for example, one of electric drivers, motor drivers, gear sets and connecting rods, or a combination thereof, but is not limited thereto.

In accordance with some embodiments, the control unit 50 may include controller area network (CAN), gigabit multimedia serial links 3 (GMSL 3), electronic control unit (ECU), but the present disclosure is not limited thereto, and other suitable control components are also applicable to the present disclosure. In accordance with some embodiments, the driving unit 60 may include linear motors, but the present disclosure is not limited thereto, and other suitable driving components are also applicable to the present disclosure.

Referring to FIG. 11, the structure of the electronic unit 10 in the electronic device 100 is further illustrated.

As shown in FIG. 11, the electronic unit 10 includes a carrier 36, a light-emitting unit 38, a fixing base 40, a diffusion plate 46, a support base 62, a light-filtering unit 42, and a cover plate 44. The light-emitting unit 38 is disposed on the carrier 36. The fixing base 40 is disposed on the light-emitting unit 38. The diffusion plate 46 is disposed on the fixing base 40. The support base 62 is disposed on the diffusion plate 46 and is electrically connected to the driving unit 60. The light-filtering unit 42 is disposed and fixed on the support base 62. The cover plate 44 is disposed on the light-filtering unit 42. It should be noted that, in the embodiment of FIG. 11, the support base 62 is disposed between the light-emitting unit 38 and the light-filtering unit 42, and is electrically connected to the driving unit 60. The light-filtering unit 42 is affixed to the support base 62. In addition, the structure and material of the light-emitting unit 38, the diffusion plate 46, the light-filtering unit 42 and the cover plate 44 shown in FIG. 11 are similar to those of the light-emitting unit 38, the diffusion plate 46, the light-filtering unit 42 and the cover plate 44 shown in FIG. 4, which will not be repeated here.

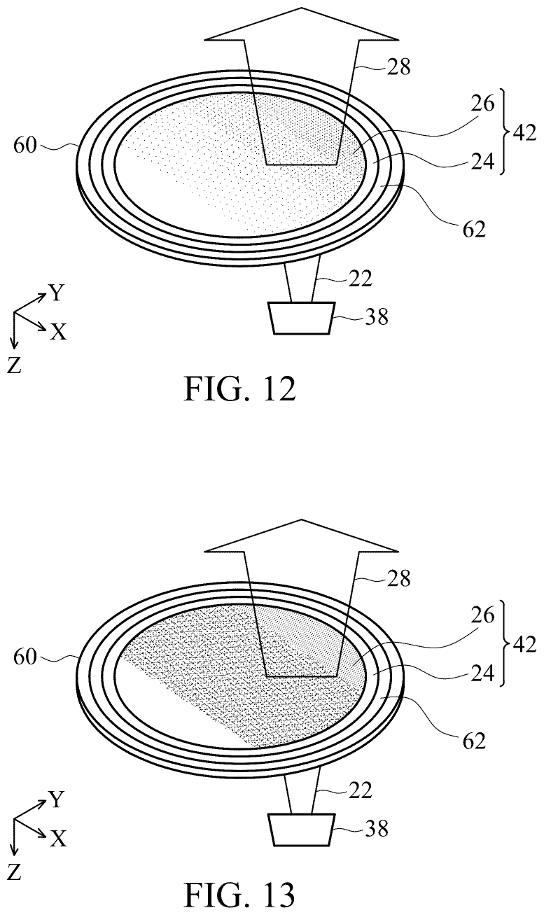

Referring to FIG. 12, which is an oblique view of some components in the electronic device 100, the operation mode of some components in the electronic device 100 is illustrated.

As shown in FIG. 12, the light-emitting unit 38 provides a first emitted light 22. At this time, a control signal (obtained by, for example, voice or touch) is input to the vehicle control unit 12 through the control unit 50 shown in FIG. 10. The vehicle control unit 12 further controls the driving unit 60, so that the support base 62 drives the light-filtering unit 42 to rotate.

In the embodiment of FIG. 12, the light-conversion layer 26 of the light-filtering unit 42 (for example, including the substrate 24 and the light-conversion layer 26 disposed on the substrate 24) is designed as a light-conversion layer including regions of different light transmittance. Therefore, when the first emitted light 22 passes through the rotating light-filtering unit 42, the brightness of the formed second emitted light 28 can be controlled.

Referring to FIG. 13, which is an oblique view of some components in the electronic device 100, the operation mode of some components in the electronic device 100 is illustrated.

As shown in FIG. 13, the light-emitting unit 38 provides a first emitted light 22. At this time, a control signal (obtained by, for example, voice or touch) is input to the vehicle control unit 12 through the control unit 50 shown in FIG. 10. The vehicle control unit 12 further controls the driving unit 60, so that the support base 62 drives the light-filtering unit 42 to rotate.

In the embodiment of FIG. 13, the light-conversion layer 26 of the light-filtering unit 42 (for example, including the substrate 24 and the light-conversion layer 26 disposed on the substrate 24) is designed as a light-conversion layer including regions of different color. Therefore, when the first emitted light 22 passes through the rotating light-filtering unit 42, the color of the formed second emitted light 28 can be controlled.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
an electronic unit, comprising:
a light-emitting unit that provides a first emitted light; and
a first light-filtering unit disposed on the light-emitting unit, wherein the first light-filtering unit comprises:
a substrate; and
a first light-conversion layer disposed on the substrate;
a vehicle control unit electrically connected to the light-emitting unit; and
a sensing unit transmitting a sensing signal to the vehicle control unit,
wherein the vehicle control unit modulates an intensity of the first emitted light based on a sensing signal from the sensing unit, and a modulated first emitted light passes through the first light-filtering unit to form a second emitted light.

2. The electronic device as claimed in claim 1, wherein the first light-filtering unit further comprises a second light-conversion layer disposed on the substrate, and the first light-conversion layer is separated from the second light-conversion layer by a distance.

3. The electronic device as claimed in claim 2, wherein the distance is 2.0-20.0 mm.

4. The electronic device as claimed in claim 1, wherein the first light-filtering unit has a light transmittance which is less than or equal to 30% or greater than or equal to 80%.

5. The electronic device as claimed in claim 1, wherein the sensing unit comprises an ambient-light sensor (ALS).

6. The electronic device as claimed in claim 1, wherein the electronic unit further comprises a cover plate disposed on the first light-filtering unit.

7. The electronic device as claimed in claim 6, wherein the electronic unit further comprises a second light-filtering unit disposed on the cover plate.

8. The electronic device as claimed in claim 7, wherein the second light-filtering unit comprises a pattern area.

9. The electronic device as claimed in claim 8, wherein the first light-conversion layer has a surface area which is greater than or equal to that of the pattern area.

10. The electronic device as claimed in claim 1, wherein the first emitted light has a first transmittance chromaticity coordinates (x1, y1), the second emitted light has a second transmittance chromaticity coordinates (x2, y2), and 0.003<|x1-x2|<0.2 and 0.003<|y1-y2|<0.2.

11. The electronic device as claimed in claim 1, wherein the electronic unit further comprises a diffusion plate disposed between the light-emitting unit and the first light-filtering unit.

12. The electronic device as claimed in claim 1, wherein the electronic unit further comprises a touch unit disposed on the first light-filtering unit and electrically connected to the vehicle control unit.

13. An electronic device, comprising:
an electronic unit, comprising:
a first light-emitting unit that provides a first emitted light;
a second light-emitting unit that provides another first emitted light;
a first light-filtering unit disposed on the first light-emitting unit and the second light-emitting unit, wherein the first light-filtering unit comprises:
a substrate;
a first light-conversion layer disposed on the substrate and corresponding to the first light-emitting unit; and
a second light-conversion layer disposed on the substrate and corresponding to the second light-emitting unit; and
a second light-filtering unit disposed on the first light-emitting unit and the second light-emitting unit;
a vehicle control unit;
a first control unit electrically connected to the vehicle control unit; and
a second control unit electrically connected to the first light-emitting unit, the second light-emitting unit and the vehicle control unit,
wherein based on a control signal from the first control unit, the vehicle control unit controls light emission of the first light-emitting unit and the second light-emitting unit through the second control unit, so as to modulate light intensity of the first emitted light and the other first emitted light, the first emitted light passes through the first light-filtering unit to form a second emitted light, the other first emitted light passes through the first light-filtering unit to form another second emitted light, and the second emitted light and the other second emitted light pass through the second light-filtering unit to form a third emitted light.

14. The electronic device as claimed in claim 13, wherein the second control unit comprises a local-dimming control unit.

15. The electronic device as claimed in claim 13, wherein the electronic unit further comprises a light-guide layer disposed on the first light-filtering unit, and the second emitted light passes through the light-guide layer to form the third emitted light.

16. The electronic device as claimed in claim 15, wherein the electronic unit further comprises a cover plate disposed on the light-guide layer.

17. The electronic device as claimed in claim 16, wherein the second light-filtering unit is disposed on the cover plate.

18. An electronic device, comprising:
an electronic unit, comprising:
a light-emitting unit that provides a first emitted light; and
a light-filtering unit disposed on the light-emitting unit, wherein the light-filtering unit comprises a substrate and a light-conversion layer disposed on the substrate;
a vehicle control unit electrically connected to the light-emitting unit;
a control unit electrically connected to the vehicle control unit; and
a driving unit electrically connected to the vehicle control unit,
wherein based on a control signal from the control unit, the vehicle control unit controls rotation of the light-filtering unit through the driving unit, and the first emitted light passes through the light-filtering unit to form a second emitted light.

19. The electronic device as claimed in claim 18, wherein the light-conversion layer comprises regions of different light transmittance.

20. The electronic device as claimed in claim 16, wherein the electronic unit further comprises a support base disposed between the light-emitting unit and the light-filtering unit and electrically connected to the driving unit, and the light-filtering unit is affixed to the support base.
